(19) United States
(12) Patent Application Publication
(10) Pub. No.: US 2005/0101050 A1
(43) Pub. Date: May 12, 2005

(54) Photolithograph system and method for driving the same

(75) Inventor: Pill Je Park, Kyongeangbuk-do (KR)

Correspondence Address: BRINKS HOFER GILSON & LIONE, P.O. BOX 10395, CHICAGO, IL, 60610, US

(73) Assignee: LG PHILIPS LCD CO., LTD.

(21) Appl. No.: 10/876,004

(22) Filed: Jun. 24, 2004

(30) Foreign Application Priority Data
Nov. 7, 2003 (KR) P 2003-78747
May 21, 2004 (KR) P 2004-36334

(51) Int. Cl. G03G 15/00; G03G 15/04; G03G 15/22; H01L 21/00; H01L 29/80; H01L 31/112

(52) U.S. Cl. 438/69; 399/4

(57) ABSTRACT

A photolithographic system and a method for driving the same is disclosed that prevents a no-load operation and imbalance in a fabrication process generated by time differences between different stages of the fabrication process. The apparatus includes a first plate storing a substrate coated with a photosensitive layer before an exposure process, a second plate storing an exposed substrate before a development process, and an auxiliary buffer plate part storing the exposed substrate before the development process when another exposed substrate has been previously stored in the second plate.

### PRIORITY CLAIM

This application claims the benefit of priority to Korean Application Nos. P2003-78747 filed on Nov. 7, 2003, and P2004-36334 filed on May 20, 2004, which are hereby incorporated by reference.

### BACKGROUND OF THE INVENTION

1. Field of the Invention

The present invention relates to a photolithographic system for fabricating a liquid crystal display (LCD) device, and more particularly, to a photolithographic system and a method for driving the same, to prevent no-load operation and imbalance of the fabrication process generated by time difference of the fabrication process.

2. Description of the Related Art

Generally, a liquid crystal display (hereinafter, referred to as an LCD) device has low power consumption, a driving low voltage, full-color realization, a thin profile and is lightweight. The LCD device is used in various fields for watches, calculators, PC monitors, notebook computers, aircrafts monitors and personal mobile terminals.

The LCD device includes an LCD panel displaying a picture image, and a driving circuit part driving the LCD panel. FIG. 1 is a layout illustrating a general LCD panel. As shown in FIG. 1, the general LCD panel includes a first substrate 1 for a thin film transistor array, a second substrate 2 for a color filter array, and a liquid crystal layer 3 between the two substrates 1 and 2.

More specifically, the first substrate 1 includes a plurality of gate lines 4 arranged in one direction at fixed intervals, a plurality of data lines 5 perpendicular to the gate lines 4 to define a plurality of pixel regions P, a plurality of pixel electrodes 6 in the respective pixel regions P to display the image, and a plurality of thin film transistors T formed in the respective pixel regions at crossing portions of the plurality of gate and data lines 4 and 5. The thin film transistors T are turned on/off by driving signals of the gate lines 4 to transmit video signals of the data lines to the respective pixel electrodes 6. Also, the second substrate 2 for the color filter array includes a black matrix layer 7 preventing light leakage on the portions except the pixel regions P, R/G/B color filter layers 8 displaying various colors in the respective pixel regions P, and a common electrode 9 formed on an entire surface of the substrate including the color filter layers 8. In case of an In-Plane Switching (IPS) mode LCD device, the common electrode 9 is formed on the first substrate 1 rather than the second substrate 9.

The thin film transistor T includes a gate electrode projecting from the gate line 4, a gate insulating layer on an entire surface of the first substrate including the gate electrode, an island-shaped active layer on the gate insulating layer above the gate electrode, a source electrode projecting from the data line 5 and overlapped with one side of the active layer, and a drain electrode opposite to the source electrode and overlapped with the other side of the active layer. Also, the pixel electrode 6 is formed of transparent conductive metal having a high transmittance such as ITO (Indium-Tin-Oxide).

A method for fabricating the aforementioned LCD panel includes three steps, an array process forming switching devices such as line patterns and thin film transistors TFT on a glass substrate, a cell process forming a liquid crystal layer between opposing two substrates after alignment and spacer arrangement steps, and a module process mounting a driver IC and a backlight. The array process includes deposition of a material for patterning on the substrate, a photolithographic process of defining regions for patterning, and etching process of the material. Also, the photolithographic process includes steps of loading the substrate having the material layer for patterning, pretreatment of cleaning and carrying out a thermal treatment to the loaded substrate, coating a photosensitive layer on the substrate, arranging a mask having the pattern thereon, exposing the photosensitive layer by irradiating ultraviolet rays on the mask, and developing the exposed photosensitive layer by developer, and unloading the substrate.

A photolithographic device for the photolithographic process will be described as follows. FIG. 2 is a schematic view illustrating the fabrication process line for photolithography according to the related art. Referring to FIG. 2, the process line for photolithography includes a loading/unloading part 10 for loading and unloading a substrate, pretreatment parts 12a and 12b for cleaning and heating the loaded substrate, coating parts 14a and 14b for coating a photosensitive layer on the substrate, an exposure part 16 for exposing the coated substrate after arranging a mask on the substrate, development parts 15a and 15b for developing the photosensitive layer on the exposed substrate, a plurality of robot parts 11a to 11e transferring the substrate loaded by the loading/unloading part 10 to the respective process steps, and a plurality of buffer plate parts 13a to 13d temporarily storing the substrate before and after the process steps.

An operation of the process line for photolithography according to the related art will be described as follows.

When the substrate is loaded to the loading/unloading part 10, the robot part 1a loads the substrate to the pretreatment parts 12a and 12b for carrying out cleaning and heating. Then, the substrate is loaded to the coating parts 14a and 14b by the robot part 11b, so that the photosensitive layer is coated on the loaded substrate. After that, the robot part 11c unloads the coated substrate, and then the unloaded substrate is provided to the buffer plate part 13c.

Then, the robot part 11d loads the substrate provided in the buffer plate part 13c to the buffer plate part 13d. Subsequently, the robot part 11e loads the substrate provided in the buffer plate part 13d to the exposure part 16, whereby the substrate is exposed with light after arranging the mask thereon. Also, the robot part 11e loads the exposed substrate to the buffer plate part 13d. At this time, the robot part 11d provides the exposed substrate to the development parts 15a and 15b, thereby carrying out the development process on the substrate. After completing the development process, the substrate is provided to the buffer plate part 13c, and then the substrate is unloaded by the robot parts 11a, 11b and 11c.

Hereinafter, the coating parts 14a and 14b, the development parts 15a and 15b, the exposure part 16, the buffer plate part 13d and the robot parts 11d and 11e will be described in detail.

FIG. 3 only illustrates the coating parts 14a and 14b, the development parts 15a and 15b, the exposure part 16, the buffer plate part 13d and the robot parts 11d and 11e, and FIG. 4 schematically illustrates the buffer plate part and the robot part. The coating parts 14a and 14b are referred to as a coating part 14, the development parts 15a and 15b are referred to as a development part 15, the buffer plate part 13d is referred to as a buffer plate part 40, and the robot parts 11d and 11e are referred to as a first robot part 11d and a second robot part 11e.

In FIG. 3, as described above, the coated substrate is temporarily stored in the buffer plate part 40 before the substrate is provided to the exposure part 16. Also, the exposed substrate is temporarily stored in the buffer plate part 40 before the substrate is loaded to the development part 15. Accordingly, the buffer plate part 40 is provided with a lower plate 41 temporarily storing the coated substrate before loading to the exposure process, and an upper plate 42 provided above the lower plate 41 to temporarily store the exposed substrate before loading to the development process.

The first and second robot parts 11d and 11e are provided at both sides of the buffer plate part 40. At this time, the coated substrate is stored in the lower plate 41, and the exposed substrate stored in the upper plate 42 is loaded to the development part 15 by the first robot part 11d. Also, the coated substrate stored in the lower plate 41 is loaded to the exposure part 16 by the second robot part 11e. Further, the exposed substrate is unloaded from the exposure part 16, and then stored in the upper plate 42 by the second robot part 11e. At this time, the first robot part 11d unloads the developed substrate.

In FIG. 3, letters A, B, C and D show the movement of the substrate in the process line for photolithography. That is, the substrate is transferred to the lower plate 41 of the buffer plate part 40 from the coating part 14 (A), and then temporarily stored in the lower plate 41 of the buffer plate 40. Then, the substrate is loaded to the exposure part 16 (B), and transferred to the upper plate 42 of the buffer plate part 40 (C) after completing the exposure process. Thereafter, the substrate stored in the upper plate 42 is loaded to the development part 15 (D), and then the substrate is unloaded after completing the development process. The exposure process of the exposure part 16 is classified into an FDC (Fast Distortion Control) for simple alignment, and an ADC (All Distortion Control) for precise alignment, on the basis of the alignment level between the substrate and mask. Thus, in the exposure process, some glass substrates from the set of the loaded substrates are precisely aligned when exposed. If there are no errors in alignment between the substrate and mask, the other substrates are exposed using simple alignment.

However, the exposure process using precise alignment requires a longer exposure time (hereinafter, referred to as a cycle time) than that of the exposure process using simple alignment. For example, the cycle time of the exposure process using simple alignment is about 67 seconds, and the cycle time of the exposure process using precise alignment is about 101 seconds. Also, the development process is about 70 seconds, and the cycle time of the coating process is shorter than that of the exposure process or the development process. Accordingly, each photolithographic process has a different cycle time, thereby generating time differences. If the substrate is exposed using precise alignment, the time required for photolithography depends on the exposure process. On the other hand, if the substrate is exposed using simple alignment, the time required for photolithography depends on the development process.

However, the related art photolithographic system, especially, the buffer plate part, has the following disadvantages.

At the beginning of photolithography, three substrates are exposed using precise alignment. If the aforementioned cycle time exists in each process, the development part 15 has a no-load operation or has to pause the system twice during the exposure process of the three substrates. As the number of the substrates exposed in precise alignment increases, the length of time increases due to increasing numbers of no-load operations or system pauses. If the substrate is exposed using simple alignment, the exposure process is processed rapidly as compared with the development process. This means that the second robot part 11e adjacent to the exposure part 16 waits, thereby lowering productivity.

### SUMMARY OF THE INVENTION

A photolithographic system and a method for driving the same, is provided to prevent no-load operation and imbalance of the fabrication process generated by time differences between various individual processes in the overall fabrication process.

In one aspect of the invention, as embodied and broadly described herein, a photolithographic system includes a first plate storing a substrate coated with a photosensitive layer before an exposure process; a second plate to store an exposed substrate before a development process; and an auxiliary buffer plate part to store the exposed substrate before the development process when a different exposed substrate is stored in the second plate.

In another aspect of the invention, the photolithographic system includes a coating part coating a photosensitive layer on a substrate; an exposure part exposing the coated substrate using precise alignment or simple alignment, exposure using precise alignment having a longer cycle time than exposure using simple alignment; a development part developing the exposed substrate; a main buffer plate part storing the coated substrate before the coated substrate is provided to the exposure part, and storing the exposed substrate before the exposed substrate is provided to the development part; an auxiliary buffer plate part storing the exposed substrate before the exposed substrates is provided to the development part when another exposed substrate is stored in the main buffer plate part; a first robot part loading the coated substrate to the main buffer plate part, or providing the exposed substrate loaded on the main buffer plate part or the auxiliary buffer plate part to the development part; and a second robot part providing the coated substrate loaded on the main buffer plate part to the exposure part, or loading the exposed substrate in the exposure part to the main buffer plate part or the auxiliary buffer plate part.

In another aspect of the invention, the photolithographic system includes a coating part coating a photosensitive layer on a substrate; an exposure part exposing the coated substrate using precise alignment or simple alignment, exposure using precise alignment having a longer cycle time than exposure using simple alignment; a development part developing the exposed substrate; a main buffer plate part having first and second plates storing the coated substrate before the coated substrate is provided to the exposure part and the exposed substrate before the exposed substrate is provided to the development part; a first robot part loading the coated substrate to the main buffer plate part or providing the exposed substrate loaded on the main buffer plate part to the development part; and a second robot part providing the coated substrate loaded on the main buffer plate part to the exposure part or loading the exposed substrate in the exposure part to the main buffer plate part.

A method for driving a photolithographic system includes providing a Look-up Table recording a specific ID, a processing state and position of each substrate in the system; loading a coated substrate to a first unoccupied plate of the main buffer plate part using the first robot part or loading an exposed substrate to a second unoccupied plate of the main buffer plate part using the second robot part; and providing the coated substrate loaded on the main buffer plate part to the exposure part using the second robot part or providing the exposed substrate loaded on the main buffer plate part to the development part using the first robot part.

In another aspect, the method includes coating a substrate with a photosensitive layer; transferring the coated substrate to a first holder of a storage unit; storing the coated substrate using the first holder until no other substrate is present in an exposure part; transferring the coated substrate to the exposure part; exposing the coated substrate in the exposure part to radiation; transferring the exposed substrate to a second holder of the storage unit if no substrate is present in the second holder and transferring the exposed substrate to a third holder of the storage unit if another exposed substrate is present in the second holder; storing all exposed substrates in different holders of the storage unit until no other substrate is present in a development part; transferring one of the exposed substrates stored in the storage unit to the development part; and developing the exposed substrate in the development part.

In another aspect, the method includes coating a substrate with a photosensitive layer; transferring the coated substrate to a storage unit having multiple holders using a first transfer apparatus; storing the coated substrate in the storage unit until no other substrate is present in an exposure part; transferring the coated substrate to the exposure part using a second transfer apparatus; exposing the coated substrate in the exposure part to radiation; transferring the exposed substrate to the storage unit using the second transfer apparatus; storing the exposed substrate in the storage unit until no other substrate is present in a development part; transferring one of the exposed substrates stored in the storage unit to the development part using the first transfer apparatus; and developing the exposed substrate in the development part. In this aspect, the first and second transfer apparatuses are capable of synchronous transfer of different substrates to different locations.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a perspective view illustrating some portions of a general LCD device;

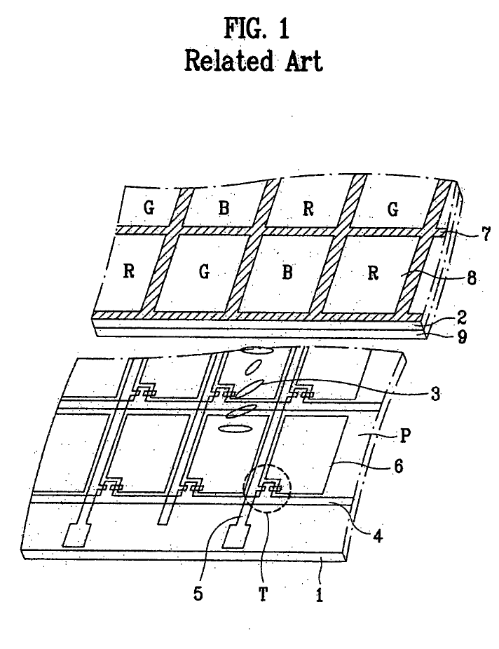

FIG. 2 is a schematic view illustrating the process line for photolithography according to the related art;

FIG. 3 is a schematic view illustrating a coating part, a development part, an exposure part and a buffer plate part of FIG. 2;

FIG. 4 is a cross-sectional view illustrating a buffer plate part and a robot part according to the related art;

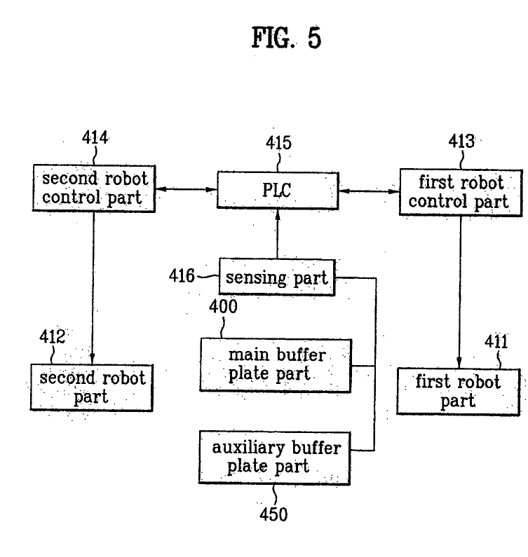

FIG. 5 is a block diagram illustrating a driving circuit of a buffer plate assembly in a photolithographic system according to the present invention;

FIG. 6 is a cross-sectional view illustrating a buffer plate part and a robot part in a buffer plate assembly of a photolithographic system according to the first embodiment of the present invention;

FIG. 7 is a cross-sectional view illustrating a buffer plate part and a robot part in a buffer plate assembly of a photolithographic system according to the second embodiment of the present invention; and

FIG. 8A to FIG. 8C are explanation views illustrating a Look-Up Table according to the second embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a buffer plate assembly according to the present invention and a method for driving the same will be described with reference to the accompanying drawings.

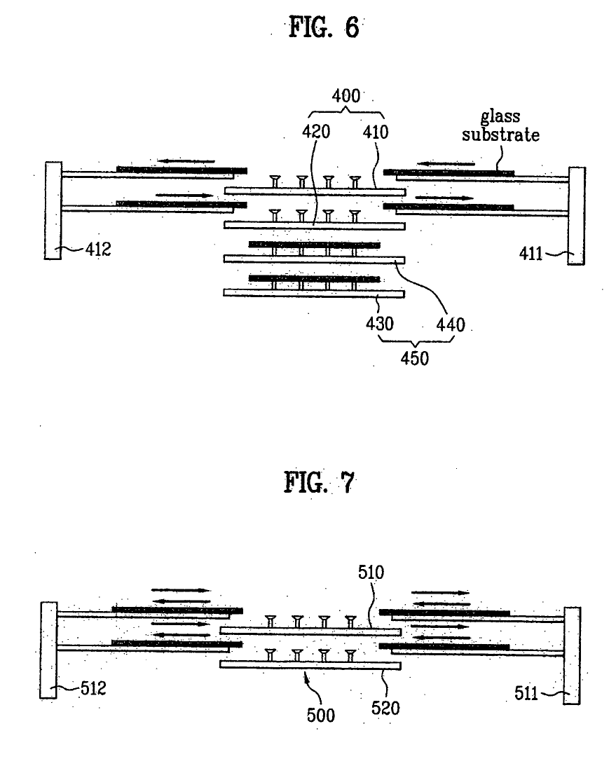

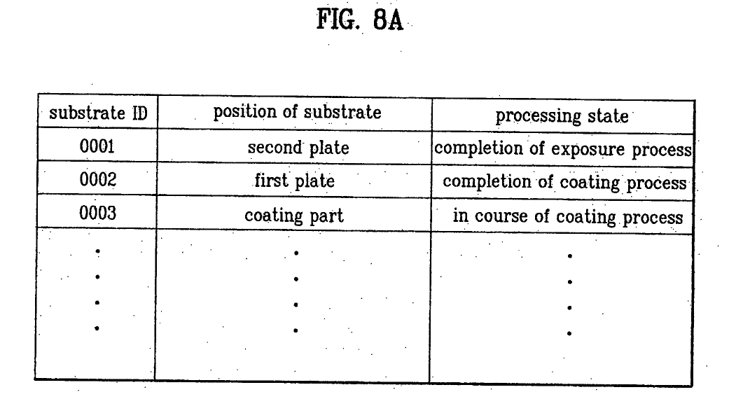

FIG. 5 is a block diagram illustrating a driving circuit of a buffer plate assembly according to the present invention. FIG. 6 is a cross-sectional view illustrating a main buffer plate part, an auxiliary buffer plate and a robot part in a buffer plate assembly according to the first embodiment of the present invention.

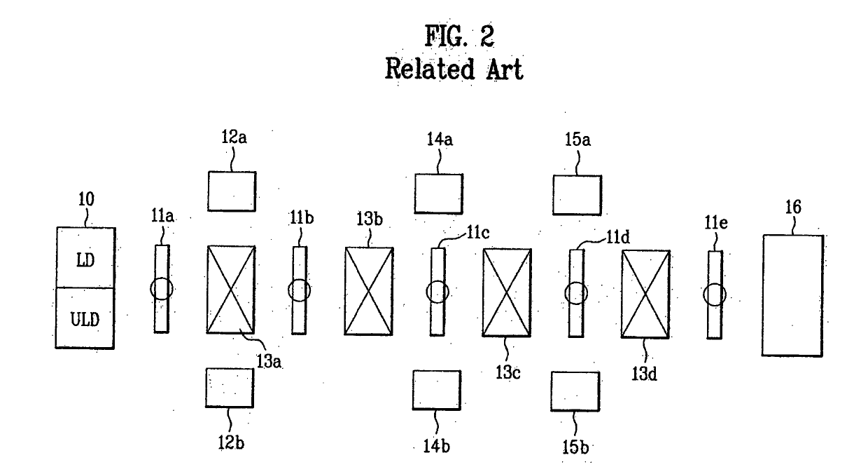

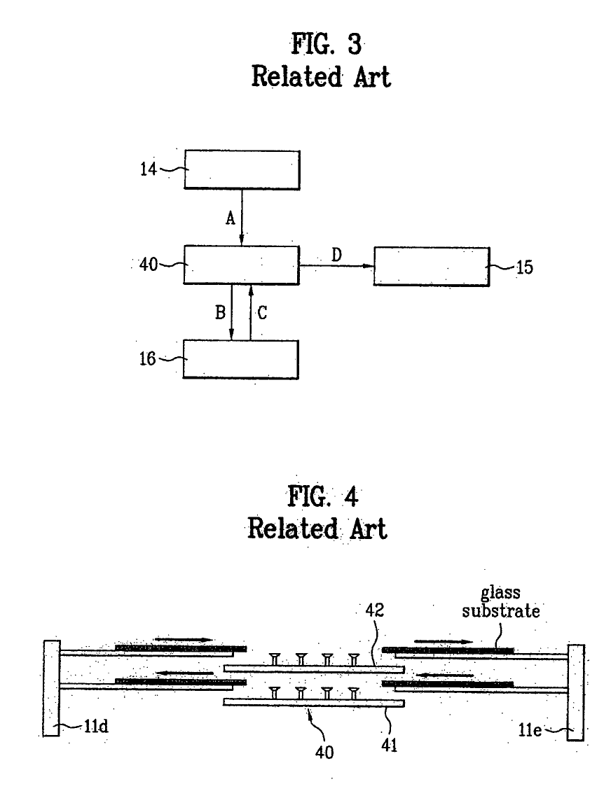

Like the photolithographic system according to the related art, the photolithographic system according to the first embodiment of the present invention includes a coating process, an exposure process and a development process. Accordingly, a coating part, an exposure part and a development part of the photolithographic system according to the present invention have the same structure as those of the related art shown in FIG. 2 and FIG. 3. However, a buffer plate assembly according to the present invention includes a main buffer plate part and an auxiliary buffer plate part. Also, the exposure process includes different steps, depending on whether simple alignment or precise alignment is carried out. For example, some substrates from a set of the coated substrates are exposed using precise alignment, which has a long cycle time. If there are no errors in alignment of the substrate and mask, the remaining substrates are exposed using simple alignment, which has a short cycle time.

In the driving circuit of the buffer plate assembly in the process line for photolithography according to the present invention, as shown in FIG. 5, a photosensitive layer is coated on the substrate by the coating part (‘14’ of FIG. 3). Then, before the coated substrate is provided to the exposure part (‘16’ of FIG. 3) or the exposed substrate is provided to the development part (‘15’ of FIG. 3), the substrate is temporarily stored in the main buffer plate part 400. If no substrate is present to load into the development part (‘15’ of FIG. 3) in the main buffer plate part 400, the auxiliary buffer plate 450 temporarily stores the exposed substrate. Also, a first robot part 411 is provided at one side of the main buffer plate part 400 and the auxiliary buffer plate 450, whereby the substrate unloaded from the coating part (‘14’ of FIG. 3) is loaded into the main buffer plate part 400, or the substrate temporarily stored in the main buffer plate part 400 or the auxiliary buffer plate part 450 is loaded into the development part (‘15’ of FIG. 3) by the first robot part 411. Then, a second robot part 412 loads the substrate stored in the main buffer plate part 400 into the exposure part (‘16’ of FIG. 3), or loads the substrate unloaded from the exposure part (‘16’ of FIG. 3) into the main buffer plate part 400 or the auxiliary buffer plate part 450. A sensing part 416 is provided to sense whether the substrate is loaded to the main buffer plate part 400 and the auxiliary buffer plate part 450 or not. Also, first and second robot control parts 413 and 414 respectively control the first and second robot parts 411 and 412, and a programmable logic circuit (PLC) 415 calculates a value sensed by the sensing part 416, and transmits the calculated value to the first and second robot control parts 413 and 414.

As shown in FIG. 6, the buffer plate assembly of the photolithographic system according to the first embodiment of the present invention is provided with the main buffer plate part 400, and the auxiliary buffer plate part 450. The main buffer plate part 400 includes a first plate 410 and a second plate 420. The first plate 410 temporarily stores the coated substrate before loading the coated substrate to the exposure part. The second plate 420 is provided below the first plate 410 to temporarily store the substrate that has been unloaded from the exposure part (‘16’ of FIG. 3) before loading this exposed substrate to the development part 15. The auxiliary buffer plate part 450 includes third and fourth plates 430 and 440. The third and fourth plates 430 and 440 temporarily store exposed substrates in case the substrate not loaded to the development part (‘15’ of FIG. 3) is maintained in the second plate 420 of the main buffer plate 400.

Like the related art, the exposure cycle time using simple alignment requires about 67 seconds and the exposure cycle time using precise alignment requires about 101 seconds. The development process requires a cycle time of about 70 seconds. If the cycle time of the coating process is shorter than that of the exposure process or the development process, the auxiliary buffer plate part 450 stores the extra substrates that have completed the exposure process as the exposure process of the substrate progresses using simple alignment.

If the substrate is not provided to the development part (‘15’ of FIG. 3) by the second plate 420, the auxiliary buffer plate part 450 provides the substrate for the development process. Preferably, if the exposure process uses precise alignment, the auxiliary buffer plate part 450 stores the substrates, corresponding to the number of times of no-load operations or pauses of the system exist in the development part of the related art photolithographic system. That is, like the related art, the cycle time of the exposure process using simple alignment is about 67 seconds, and the cycle time of the exposure process using precise alignment is about 101 seconds. Also, the cycle time in the development process is about 70 seconds. Accordingly, the substrate is exposed using precise alignment by the exposure part (‘16’ of FIG. 3), the development part (‘15’ of FIG. 3) has two no-load operations, so that it is preferable for the auxiliary buffer plate part 450 to have at least two plates.

The first robot part 411 is provided at one side of the buffer plate assembly 400. The first robot part 411 loads the coated substrate to the first plate 410. If a substrate is stored in the second plate 420, the first robot part 411 loads the substrate stored in the second plate 420 to the development part (‘15’ of FIG. 3). If a substrate is not stored in the second plate 420, the first robot part 411 loads a substrate stored in the auxiliary buffer plate part 450 to the development part (‘15’ of FIG. 3).

The second robot part 412 is provided at the other side of the buffer plate assembly 400. The second robot part 412 loads the substrate stored in the first plate 410 to the exposure part (‘16’ of FIG. 3), and loads the exposed substrate unloaded from the exposure part (‘16’ of FIG. 3) to the second plate 420. If the second plate 420 stores a substrate which has not yet been loaded to the development part (‘15’ of FIG. 3), the second robot part 412 loads the substrate which was to be stored in the second plate 420 to the third or fourth plate 430 or 440. In the aforementioned description, it is possible to change the position of the upper and lower plates in the buffer plate assembly. Also, the buffer plate assembly 400 is provided with a sensing part 416 to sense whether substrates are provided in the respective plates 410, 420, 430 and 440.

Operation of the photolithographic system having the aforementioned buffer plate assembly according to the first embodiment of the present invention will be described as follows.

First, if the coated substrate is stored in the first plate 410 of the main buffer plate part 400 by the first robot part 411, the second robot part 412 loads the substrate stored in the first plate 410 to the exposure part (‘16’ of FIG. 3). At the beginning of photolithography, some substrates are exposed using precise alignment, and then unloaded from the exposure part (‘16’ of FIG. 3) by the second robot part 412. Subsequently, one of the exposed substrates is stored in the second plate 420, and this substrate stored in the second plate 420 is loaded to the development part (‘15’ of FIG. 3) by the first robot part 411, whereby the development process is carried out.

After some substrates complete the exposure process in the exposure part (‘16’ of FIG. 3) using precise alignment, the substrate stored in the first plate 410 is loaded to the exposure part (‘16’ of FIG. 3) and the exposure process using simple alignment is carried out. As the number of substrates exposed increases because simple alignment has been used, the second plate 420 has an exposed substrate already stored therein. Ann exposed substrate is unloaded from the exposure part by the second robot part 412 and the sensing part 416 senses that the second plate 420 already has an exposed substrate contained therein. Accordingly, the second robot part 412 loads the exposed substrate to the auxiliary buffer plate part 450 rather than the second plate 420.

Then, the new set of substrates is loaded and the exposure process using precise alignment is carried out, whereby the exposure time increases. To prevent a no-load operation of the development part (‘15’ of FIG. 3), the first robot part 411 loads the substrate temporarily stored in the second plate 420 of the main buffer plate part 400 to the development part (‘15’ of FIG. 3). If the second plate 420 does not contain an exposed substrate, a substrate stored in the auxiliary buffer plate part 450 is loaded to the development part (‘15’ of FIG. 3). Supporters provided in the first robot part 411 and the second robot part 412 move up and down or the buffer plate assembly 400 may be moved up and down to store the substrate in the auxiliary buffer plate part 450 or to unload the substrate stored in the auxiliary buffer plate part 450.

In the buffer plate assembly according to the present invention, it is possible to prevent a no-load operation or pause of the system by controlling the first and second robot parts without additional auxiliary buffer plate parts being used. This will be described as follows.

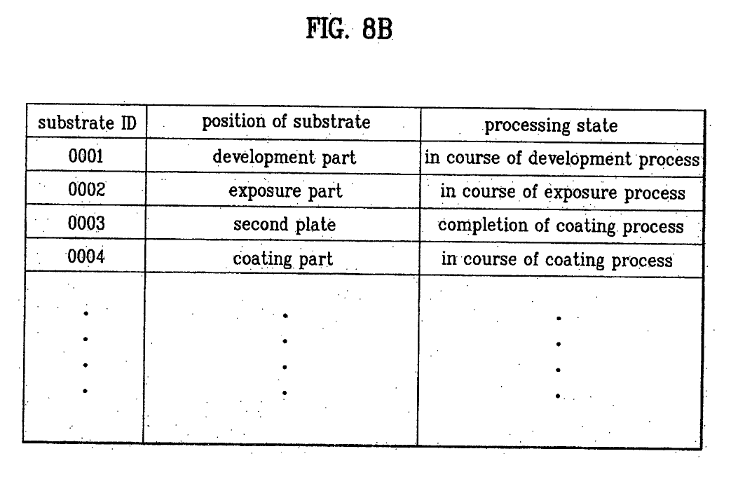

FIG. 7 is a cross-sectional view illustrating a buffer plate part and a robot part in a buffer plate assembly of a photolithographic system according to the second embodiment of the present invention.

Referring to FIG. 7, the buffer plate assembly according to the second embodiment of the present invention uses a main buffer plate part 500 having a first plate 510 and a second plate 520. Each of the first and second plates 510 and 520 is operated using a bi-directional transfer method. As a result, the photolithographic system according to the second embodiment of the present invention enables synchronous transfer, making it possible to drive the buffer plate assembly according to the second embodiment of the present invention without an auxiliary buffer plate part.

First and second robot parts 511 and 512 are provided at both sides of the main buffer plate part 500. The first and second robot parts 511 and 512 load substrates to the respective plates 510 and 520 of the main buffer plate part 500 and unload the substrates from the plates 510 and 520 of the main buffer plate part 500. It is possible to load the substrates to the first plate 510 and to unload the substrates therefrom using the first and second robot parts 511 and 512. Also, it is possible to load the substrates to the second plate 520 and to unload the substrates therefrom by the first and second robot parts 511 and 512.

The photolithographic system according to the second embodiment of the present invention is provided with a coating part (‘14’ of FIG. 3), an exposure part (‘16’ of FIG. 3), a development part (‘15’ of FIG. 3), the main buffer plate part 500 having the first and second plates 510 and 520, the first robot part 511, and the second robot part 512. In detail, a photosensitive layer is coated on the substrate in the coating part. Some substrates coated with the photosensitive layer are exposed using precise alignment having a long cycle time, and the remaining substrates are exposed using simple alignment having a short cycle time. In the development part, the exposed substrates are developed. The first and second plates 510 and 520 temporarily store the coated substrates before the exposure process and temporarily store the exposed substrates before the development process. The first robot part 511 loads the coated substrates to the main buffer plate part 500 and provides the exposed substrate in the main buffer plate part 500 to the development part. The second robot part 512 provides the coated substrates of the main buffer plate part 500 to the exposure part and loads the exposed substrates to the main buffer plate part 500.

This will be described in detail. In FIG. 5, a Look-up Table is provided to a PLC 415 or first and second robot control parts 413 and 414. The Look-up Table records specific IDs, the processing state and position of the respective substrates. By controlling the first and second robot parts 411 and 412 according to the Look-up Table, it is possible to prevent a no-load operation of the development part (‘15’ of FIG. 3) without formation of an auxiliary buffer plate part.

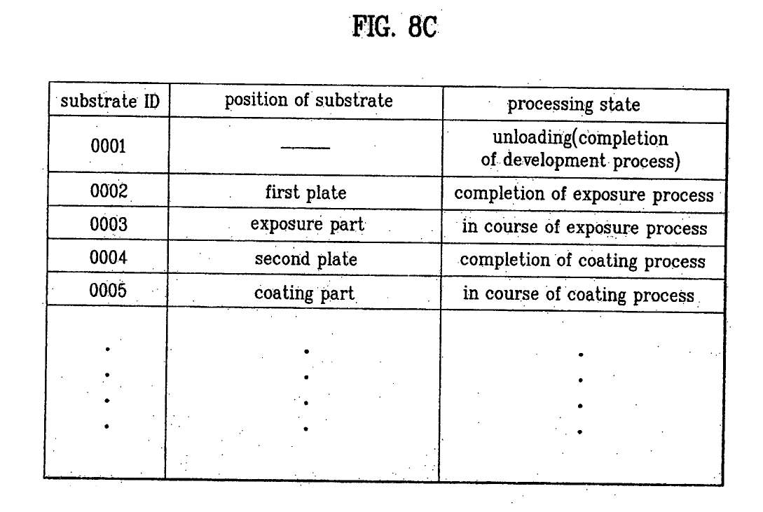

FIG. 8A to FIG. 8C illustrate the Look-Up Table according to the second embodiment of the present invention. As described above, if the recording state of FIG. 8A is provided in the Look-up Table of the PLC 415 or the first and second robot control parts 413 and 414, the first robot control part 413 controls the first robot part 511 to transfer the substrate 0001 stored in the second plate 520 to the development part (‘15’ of FIG. 3). Simultaneously, the second robot control part 414 controls the second robot part 512 to transfer the substrate 0002 stored in the first plate 510 to the exposure part (‘16’ of FIG. 3), or to load the coated substrate 0003 of the coating part (‘14’ of FIG. 3) to the second plate 520. Then, the position and the processing state corresponding to the ID of the respective substrates are newly recorded as shown in FIG. 8B.

In the state of FIG. 8B, after completion of the process in the exposure part and the development part, the second robot part 512 unloads the exposed substrate 0002 from the exposure part (‘16’ of FIG. 3), and then loads the unloaded substrate 0002 to the first plate 510. Also, the second robot part 512 unloads the developed substrate 0001. After that, the first robot part 511 transfers the substrate 0003 of the second plate 520 to the exposure part (‘16’ of FIG. 3), and the second robot part 512 transfers the substrate 0002 of the first plate 510 to the development part (‘15’ of FIG. 3). Also, the first robot part 511 loads the coated substrate 0004 to the second plate 520.

The Look-up Table of the aforementioned process is then recorded as shown in FIG. 8C. In this method, the coated or exposed substrates may be loaded to the first or second plates 510 and 520 if the plates have no substrate thereon, so that it is possible to prevent a no-load operation of the development part without an additional auxiliary buffer plate part. In addition, the aforementioned buffer plate assemblies 400 and 500 may be applied to any system having the problem of processing imbalance, as well as the photolithographic system according to the preferred embodiment of the present invention.

As mentioned above, the photolithographic system according to the present invention and the method for driving the same have the following advantages.

First, the auxiliary buffer plate assembly stores the extra substrates, so that it is possible to provide an exposed substrate to the development part when an exposure process using precise alignment is processed, thereby preventing a no-load operation or pause of the robot and development parts. As a result, it is possible to improve productivity owing to the prevention of a no-load operation or pause of the system.

Furthermore, the robot parts are controlled by the Look-up Table recording the processing state and position of the respective substrates. This makes it is possible to prevent a no-load operation or pause of the robot parts without formation of an auxiliary buffer plate part, thereby improving productivity.

It will be apparent to those skilled in the art that various modifications and variations can be made in the present invention. Thus, it is intended that the present invention covers the modifications and variations of this invention provided they come within the scope of the appended claims and their equivalents.

1. A photolithographic system comprising:
a first plate to store a substrate coated with a photosensitive layer before an exposure process;
a second plate to store an exposed substrate before a development process; and
an auxiliary buffer plate part to store the exposed substrate before the development process when a different exposed substrate is stored in the second plate.

2. The photolithographic system of claim 1, wherein the auxiliary buffer plate part contains at least one plate.

3. A photolithographic system comprising;
a coating part coating a photosensitive layer on a substrate;
an exposure part exposing the coated substrate using precise alignment or simple alignment, exposure using precise alignment having a longer cycle time than exposure using simple alignment;
a development part developing the exposed substrate;
a main buffer plate part storing the coated substrate before the coated substrate is provided to the exposure part, and storing the exposed substrate before the exposed substrate is provided to the development part;
an auxiliary buffer plate part storing the exposed substrate before the exposed substrates is provided to the development part when another exposed substrate is stored in the main buffer plate part;
a first robot part loading the coated substrate to the main buffer plate part, or providing the exposed substrate loaded on the main buffer plate part or the auxiliary buffer plate part to the development part; and
a second robot part providing the coated substrate loaded on the main buffer plate part to the exposure part, or loading the exposed substrate in the exposure part to the main buffer plate part or the auxiliary buffer plate part.

4. The photolithographic system of claim 3, wherein the main buffer plate part is provided with a first plate storing the coated substrate before the coated substrate is provided to the exposure part, and a second plate storing the exposed substrate before the exposed substrate is provided to the development part.

5. The photolithographic system of claim 3, wherein the auxiliary buffer plate part is provided with at least one plate.

6. The photolithographic system of claim 3, wherein if no exposed substrate is loaded on the main buffer plate part, the exposed substrate loaded on the auxiliary buffer plate part is provided to the development part.

7. The photolithographic system of claim 3, wherein if the other exposed substrate is loaded on the main buffer plate part, the second robot part loads the substrate exposed in the exposure part to the auxiliary buffer plate part.

8. The photolithographic system of claim 3, further comprising:
first and second robot control parts respectively controlling the first robot part and the second robot part;
a sensing part sensing whether any substrates are loaded on the main buffer plate part or the auxiliary buffer plate part; and
a programmable logic circuit processing a signal sensed from the sensing part and providing the processed signal to the first and second robot control parts.

9. A photolithographic system comprising:
a coating part coating a photosensitive layer on a substrate;
an exposure part exposing the coated substrate using precise alignment or simple alignment, exposure using precise alignment having a longer cycle time than exposure using simple alignment;
a development part developing the exposed substrate;
a main buffer plate part having first and second plates storing the coated substrate before the coated substrate is provided to the exposure part and the exposed substrate before the exposed substrate is provided to the development part;
a first robot part loading the coated substrate to the main buffer plate part or providing the exposed substrate loaded on the main buffer plate part to the development part; and
a second robot part providing the coated substrate loaded on the main buffer plate part to the exposure part or loading the exposed substrate in the exposure part to the main buffer plate part.

10. The photolithographic system of claim 9, further comprising:
first and second robot control parts respectively controlling the first robot part and the second robot part;
a sensing part sensing whether substrates are loaded on the main buffer plate part; and
a programmable logic circuit processing a signal sensed from the sensing part, and providing the processed signal to the first and second robot control parts.

11. A method for driving a photolithographic system that includes a coating part, an exposure part, a development part, a main buffer plate part, a first robot part, and a second robot part, the method comprising:
providing a Look-up Table recording a specific ID, a processing state and position of each substrate in the system;
loading a coated substrate to a first unoccupied plate of the main buffer plate part using the first robot part or loading an exposed substrate to a second unoccupied plate of the main buffer plate part using the second robot part; and
providing the coated substrate loaded on the main buffer plate part to the exposure part using the second robot part or providing the exposed substrate loaded on the main buffer plate part to the development part using the first robot part.

12. A method of processing substrates, the method comprising:
coating a substrate with a photosensitive layer;
transferring the coated substrate to a first holder of a storage unit;
storing the coated substrate using the first holder until no other substrate is present in an exposure part;
transferring the coated substrate to the exposure part;
exposing the coated substrate in the exposure part to radiation;
transferring the exposed substrate to a second holder of the storage unit if no substrate is present in the second holder and transferring the exposed substrate to a third holder of the storage unit if another exposed substrate is present in the second holder;
storing all exposed substrates in different holders of the storage unit until no other substrate is present in a development part;
transferring one of the exposed substrates stored in the storage unit to the development part; and
developing the exposed substrate in the development part.

13. The method of claim 12, further comprising storing at least three exposed substrates in the storage unit at some point during processing.

14. The method of claim 12, further comprising transferring the exposed substrate stored in the third holder to the development part only if no substrate is stored in the second holder.

15. The method of claim 12, further comprising:
sensing which of the holders contain substrates; and
controlling transfer of the substrates based on the sensing.

16. The method of claim 12, further comprising maintaining a record of a specific ID, a processing state and a position of each substrate being processed.

17. The method of claim 12, further comprising exposing a substrate using precise alignment or simple alignment, exposure using precise alignment having a longer cycle time than exposure using simple alignment.

18. A method of processing substrates, the method comprising:
coating a substrate with a photosensitive layer;
transferring the coated substrate to a storage unit having multiple holders using a first transfer apparatus;
storing the coated substrate in the storage unit until no other substrate is present in an exposure part;
transferring the coated substrate to the exposure part using a second transfer apparatus;
exposing the coated substrate in the exposure part to radiation;
transferring the exposed substrate to the storage unit using the second transfer apparatus;
storing the exposed substrate in the storage unit until no other substrate is present in a development part;
transferring one of the exposed substrates stored in the storage unit to the development part using the first transfer apparatus; and
developing the exposed substrate in the development part,
wherein the first and second transfer apparatuses are capable of synchronous transfer of different substrates to different locations.

19. The method of claim 18, wherein the storage unit comprises a maximum of two holders.

20. The method of claim 18, further comprising:
sensing which of the holders contain substrates; and
controlling transfer of the substrates based on the sensing.

21. The method of claim 18, further comprising maintaining a record of a specific ID, a processing state and a position of each substrate being processed.

22. The method of claim 18, further comprising exposing a substrate using precise alignment or simple alignment, exposure using precise alignment having a longer cycle time than exposure using simple alignment.

23. The method of claim 18, further comprising transferring the coated substrate to the storage unit or transferring the exposed substrate from the storage unit to the development part simultaneously with transferring the coated substrate from the storage unit to the exposure part or transferring the exposed substrate in the exposure part to the storage unit.
